(19) United States
(12) Patent Application Publication
(10) Pub. No.: US 2012/0097217 A1
(43) Pub. Date: Apr. 26, 2012

(54) Functionally Graded Solar Roofing Panels and Systems

(76) Inventors: Huiming Yin, New York, NY (US); Liming Li, East Brunswick, NJ (US); Pablo Prieto-Munoz, Miami, FL (US); Michael E. Lackey, New York, NY (US)

(21) Appl. No.: 13/320,044

(22) PCT Filed: May 17, 2010
(86) PCT No.: PCT/US10/35066

§ 371 Date: Dec. 21, 2011

Related U.S. Application Data
(60) Provisional application No. 61/178,721, filed on May 15, 2009.
(60) Provisional application No. 61/220,082, filed on Jun. 24, 2009.
(60) Provisional application No. 61/238,023, filed on Aug. 28, 2009.

(51) Int. Cl. H01L 31/058; H01L 31/052

(52) U.S. Cl. 136/248; 136/246

(57) ABSTRACT

Solar panels and solar heating systems are disclosed. In some embodiments, the solar panels include the following: a top protective layer; a thin-film photovoltaic layer adjacent the top layer; a bottom polymeric substrate layer opposite the top layer; and a functionally graded material interlayer positioned between the top and bottom layers, the interlayer including a first homogeneous polymeric composite layer below the thin film photovoltaic layer, a second homogeneous polymeric composite layer including water tubes below the first composite layer, and a substantially polymeric layer below the second composite layer and adjacent the bottom layer.

### CROSS REFERENCE TO RELATED APPLICATION(S)

This application claims the benefit of U.S. Provisional Application Nos. 61/178,721, filed May 15, 2009, 61/220,082, filed Jun. 24, 2009, and 61/238,023, filed Aug. 28, 2009, each of which is incorporated by reference as if disclosed herein in its entirety.

### BACKGROUND

Water cooled solar cell working under concentrated sunlight are known. However, existing technology cannot be integrated to typical roofs because of a sunlight concentrating mirror is generally required. In addition, such technology typically includes the use of copper-water as a heat sink.

The efficiency of photovoltaic modules significantly reduces with temperature elevation. For example, most existing solar panels that include silicon photovoltaic modules have a stagnation temperature at around 85 degrees Celsius, whereas the service temperature can be higher than about 90 degrees Celsius.

Existing solar panel technology is typically expensive to manufacture because of the use of silicon and integrated manufacturing. In addition, laminated fabrication methods of existing technologies often produce a panel that is susceptible to deterioration in varying weather conditions and can a high level of maintenance over its lifecycle.

In existing hybrid solar roofing systems with a heat collector, a temperature difference between warm indoor air and cold roof material can induce the vapor condensation and degrade the indoor thermal comfort.

From exposure to weather environments, existing solar roofing systems that do not include sufficient protection against UV rays often see a decay in material properties and structural strength over the service time.

### SUMMARY

Solar panels according to the disclosed subject matter and systems incorporating such panels include integrate a thin-film photovoltaic module layer, a functionally graded material interlayer with water tubes, and a plastic lumber substrate for photovoltaic-heat energy utilization. The functionally graded material interlayer includes aluminum or aluminum nitride or other higher thermal conductive particles to improve the effective thermal conductivity of the functionally graded material and thus allow the heat to be rapidly transferred into the water tubes. Some embodiments also include a thermoelectric module.

The photovoltaic module layer receives about 85% solar irradiation and transfers photovoltaic energy into electricity. To overcome the problem where unused energy heats up the photovoltaic module and unfavorably reduces photovoltaic energy utilization efficiency, the water tubes are integrated within the panel as the heat collector. The water tubes help control the service temperature and utilize the heat portion of energy. A controlled flow of cool water is passed through the tubes to transfer the heat from the panel to the water and thus control the temperature of the panel. Water heated through the panel system is collected and used for electricity generation by low temperature Rankine Cycle or domestic uses.

### BRIEF DESCRIPTION OF THE DRAWINGS

The drawings show embodiments of the disclosed subject matter for the purpose of illustrating the invention. However, it should be understood that the present application is not limited to the precise arrangements and instrumentalities shown in the drawings, wherein:

FIG. 1 is an enlarged front isometric elevation of a solar panel according to some embodiments of the disclosed subject matter;

FIG. 2 is an enlarged front isometric elevation of a solar panel according to some embodiments of the disclosed subject matter;

FIG. 3 is an enlarged front isometric elevation of a solar panel according to some embodiments of the disclosed subject matter; and

FIG. 4 is a schematic diagram of a solar heating system according to some embodiments of the disclosed subject matter.

### DETAILED DESCRIPTION

Some embodiments of the disclosed subject matter include solar panels and functionally graded solar roofing panel systems.

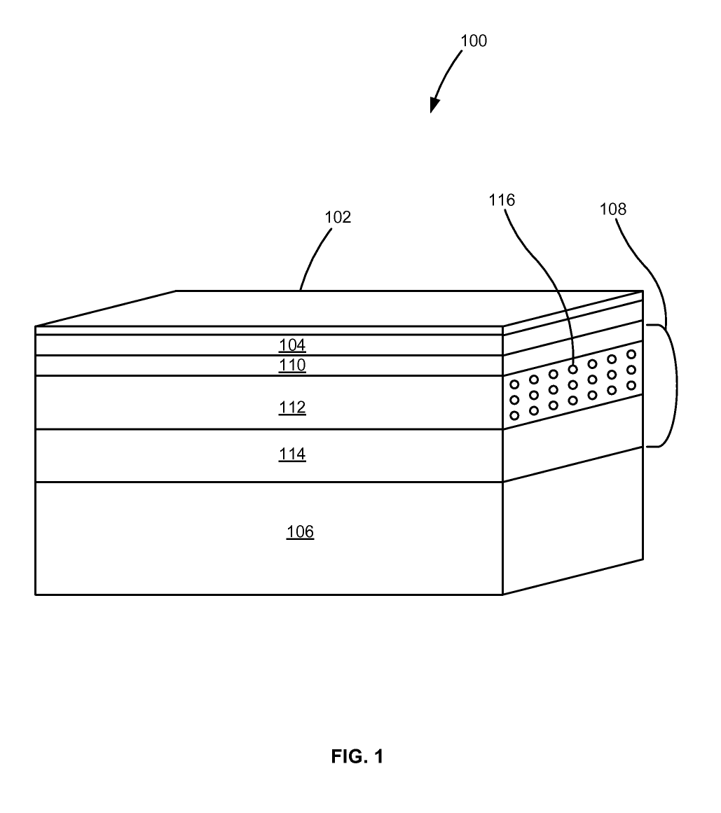

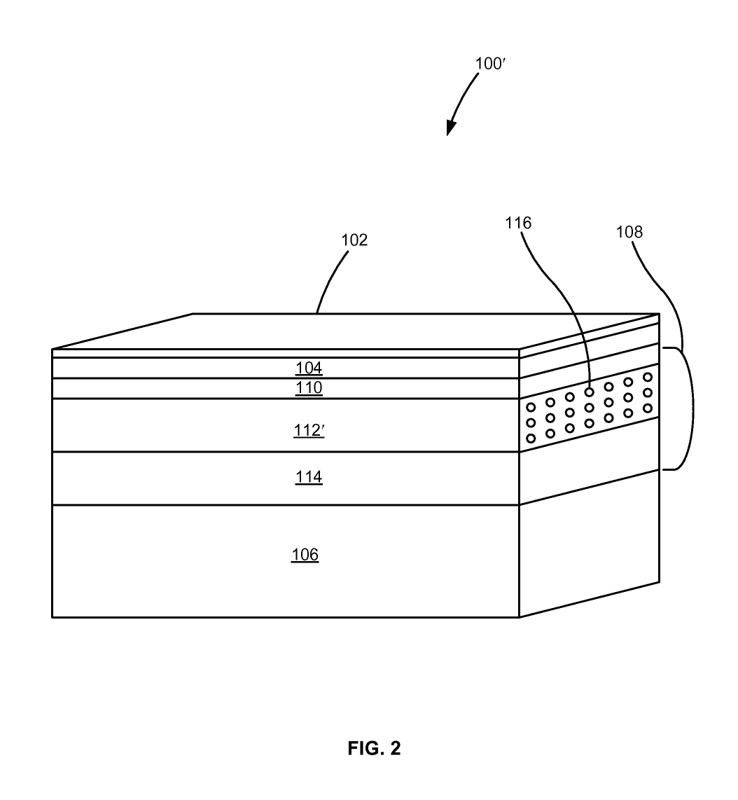

Referring now to FIGS. 1 and 2, some embodiments include a solar panel 100. Solar panel 100 is a multi-layered panel including a top protective layer 102, a thin-film photovoltaic layer 104, a bottom plastic lumber substrate layer 106, and a functionally graded material interlayer 108. Photovoltaic layer 104 converts a large portion of the solar light rays that hit the layer into usable electricity. Solar panel 100 typically has an overall thickness of about 20 mm to about 40 mm.

Top protective layer 102 is typically formed from a coating or glass-like material.

Thin-film photovoltaic layer 104 is positioned adjacent top layer 102. Thin-film photovoltaic layer 104 is fabricated from known materials used for fabricating solar panel including silicon, other inorganic materials, organic dyes, and organic polymers. Thin-film photovoltaic layer 104 typically has a thickness of about 1 mm to about 4 mm.

Bottom polymeric substrate layer 106 is positioned opposite top layer 102.

Bottom polymeric substrate layer 106 is typically fabricated from a plastic lumber or similar material that can include recycled high density polyethylene. Bottom polymeric substrate layer 106 typically has a thickness of about 10 mm to about 20 mm. Bottom polymeric substrate layer 106 serves as structural support and heat insulation of the roof. The thermo-mechanical properties of bottom polymeric substrate layer 106 are typically very close those of high density polyethylene or similar materials included in functionally graded material interlayer 108.

Functionally graded material interlayer 108 is positioned between top and bottom layers 102 and 106. Functionally graded material interlayer 108 is typically cast using a mold and typically has a thickness of about 5 mm to about 15 mm. In some embodiments, functionally graded material interlayer 108 is positioned between thin-film photovoltaic layer 104 and bottom layer 106.

Functionally graded material interlayer 108 includes a first homogeneous polymeric composite layer 110, a second homogeneous polymeric composite layer 112, and a substantially polymeric layer 114. First homogeneous polymeric composite layer 110 is positioned below thin film photovoltaic layer 104 and typically has a thickness of about 1 mm to about 3 mm. First homogeneous polymeric composite layer 110 is fabricated from a material including aluminum and high density polyethylene. Typically, aluminum powder is dispersed in a high density polyethylene matrix with a continuously varying volume fraction of aluminum. In some embodiments, first homogeneous polymeric composite layer 110 is about 50% aluminum. Second homogeneous polymeric composite layer 112 includes water tubes 116 each having a diameter of about 5 mm to about 9 mm that are cast with a center-to-center distance of about 10 mm to about 30 mm. Second homogeneous polymeric composite layer 112, which typically has an overall thickness of about 1 mm to 8 mm, is positioned below first composite layer 110. The volume fraction of aluminum in second homogeneous polymeric layer is rapidly reduced from 50% to zero thru the thickness of the layer.

As shown in FIG. 2, some embodiments include a solar panel 100′ that is fabricated substantially similarly to solar panel 100 but has a second homogeneous polymeric layer 112′ that is fabricated from a material including aluminum nitride and high density polyethylene.

Polymeric layer 114 is positioned below second composite layer 112′ and adjacent bottom layer 106. Polymeric layer 114 is typically fabricated from a material including a substantially pure high density polyethylene. Polymeric layer 114 typically has a thickness of about 8 mm to about 10 mm.

In some embodiments, functionally graded material interlayer 108 is fabricated by casting aluminum/aluminum nitride and high density polyethylene powder at about 180 degrees Celsius to about 220 degrees Celsius and 4 MPa. It can also be fabricated with a vacuum oven at a higher temperature. For mass production, an extrusion method can be utilized.

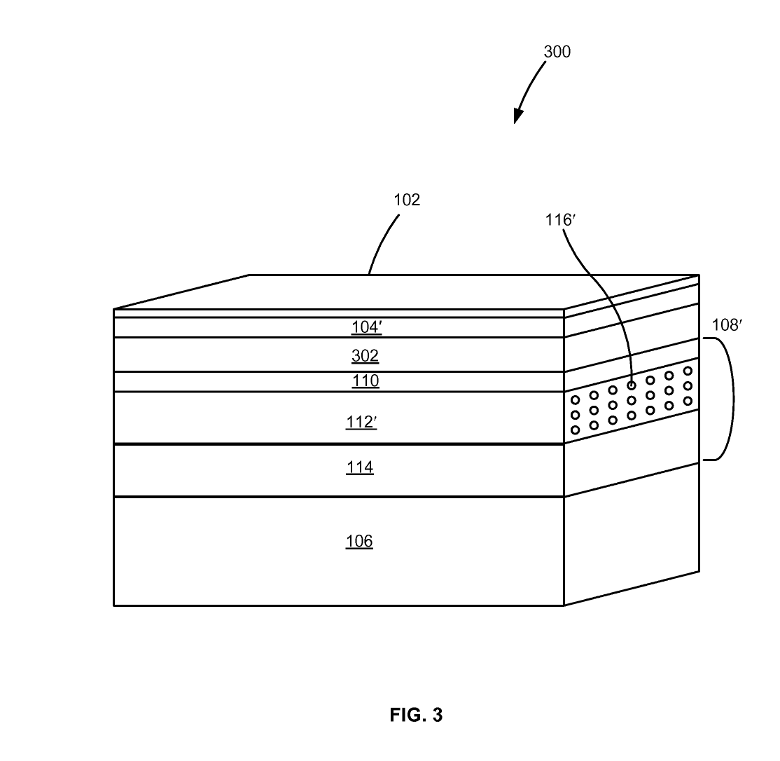

Referring now to FIG. 3, some embodiments include a solar panel 300 that is substantially similar to solar panels 100 and 100′, but includes a thermoelectric module layer 302 positioned between thin-film photovoltaic layer 104′ and said functionally graded material interlayer 108′, which includes a homogeneous polymeric composite layer 112′ having water tubes 116′. Thermoelectric module layer 302 converts the unused heat energy that is created during the process of solar irradiance into more usable electricity. The temperature difference between thin-film photovoltaic layer 104′ and water tubes 116′ provides a considerable temperature gradient within thermoelectric module layer 302 for a higher efficiency of thermoelectric utilization.

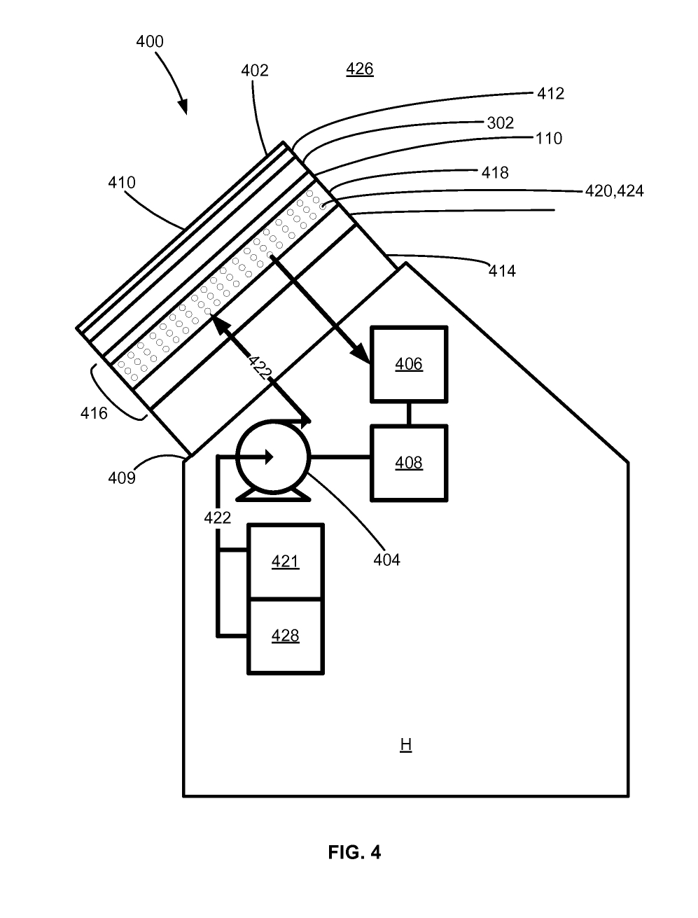

Referring now to FIG. 4, some embodiments include a solar heating system 400 including a solar panel 402, a pump 404, a distribution sub-system 406, and a control system 408. Solar panels 402 are mounted on a roof 409 of a house H. In FIG. 4, an enlarged view of solar panel 402, which is not to scale with respect to house H, is shown.

Solar panel 402 is substantially similar to solar panels 100, 100′, and 300 and includes a top protective layer 410, a thin-film photovoltaic layer 412 adjacent the top layer, a bottom polymeric substrate layer 414 opposite the top layer, and a functionally graded material interlayer 416 positioned between the top and bottom layers. Interlayer 416 has multiple layers including a homogeneous polymeric composite layer 418 having water tubes 420.

Pump 404 is used to pump cold water 421 into water tubes 420 via a conduit 422 at varying low rates. Distribution sub-system 406 controls and directs cold water 421 elsewhere for consumption after it is heated within water tubes 420. Control system 408 controls the operation of pump 404 and distribution sub-system 406 depending on temperatures within at solar panel 402, an interior 424 of water tubes 420, and an atmosphere 426 outside system 400. In some embodiments, control system 408 causes cold water 421 to automatically be introduced to water tubes 420 depending on temperatures within solar panel 420. In some embodiments, solar heating system 400 includes a source of warm water 428 that can be directed to water tubes 420 to prevent the formation of and/or melt any ice and snow on solar panel 402.

Solar panels according to the disclosed subject matter and systems incorporating such panels offer benefits over known technology. Solar panels according to the disclosed subject matter are seamlessly integrated so that the stiffer top of the functionally graded material interlayer serves as a wafer for the deposition of photovoltaic and thermoelectric thin layers and the high density polyethylene bottom is compatible with the plastic lumber substrate. A higher percentage of aluminum powder enables rapid heat transfer into water tubes, while heat conduction is blocked by the high density polyethylene bottom and the plastic lumber substrate.

The efficiency of photovoltaic modules significantly reduces with temperature elevation. For example, most silicon photovoltaic modules have a stagnation temperature at around 85 degrees Celsius, whereas the service temperature can be higher than about 90 degrees Celsius. The stable temperature control system according to the disclosed subject matter enhances the photovoltaic performance.

Due to the temperature control by the water flow, the photovoltaic module can work at lower temperatures in the summer and thus reach a higher efficiency for photovoltaic utilization. The water that is heated in the water tubes, whose temperature is partially controlled by the flow rate, can be directly used by water heating system for domestic usage. Due to the temperature control on the roof, the room temperature can be significantly reduced and thermal comfort in the building can be much improved.

The top surface of functionally graded material interlayer serves as the wafer for photovoltaic layer and the bottom surface is compatible with the substrate. Therefore, the thermal stress within the multiply layered structure is significantly reduced and the integrity of the panel is much improved.

The thermal conductivities of aluminum and high density polyethylene are around 238 and 0.5 W/(m·degrees Celsius), respectively. A high percentage of the aluminum powder will improve the effective thermal conductivity of the functionally graded material and thus allow the heat to be rapidly transferred into the water tubes, but below them the heat conduction is hindered by the high density polyethylene. The thin film photovoltaic layer reduces the usage of silicon and lowers the cost. It improves the heat conduction and structural integrity within the panel. It also protects the polymer materials below from UV radiation. The plastic lumber substrate provides the mechanical and structural support for the upper layers and thermal insulation for the indoor air.

Solar panels according to embodiments of the disclosed subject matter can be used in various weather conditions. In the summer, when the panel temperature reaches about 30 degrees Celsius, an automatic control system starts the flow of cold water through the water tubes. The flow rate can be adaptively adjusted for the desired temperature of photovoltaic layer and water. Therefore, the photovoltaic layer temperature can be maintained at or below about 50-75 degrees Celsius even during hot weather to obtain higher photovoltaic utilization efficiency. In the thickness of the panel, the temperature can be maintained within 25-50 degrees Celsius. A narrow temperature range helps reduce the thermal stress within in the panel. The temperature of traditional photovoltaic panels can easily reach 80 degrees Celsius and have even been observed higher than 100 degrees Celsius in Arizona and other warm locations.

When panel temperature is lower than 20 degrees Celsius, a control system can be configured to turn off the water flow. The air in the water tubes can serve as thermal insulation and reduce the heat transfer from the indoor air to outside. In the winter, snow on the roof can prevent photovoltaic utilization. The control system introduces a flow of warm water at 25-30 degrees Celsius into the water tubes. The warm water rapidly makes snow and ice melt and cleans up the roof panel. Therefore, the solar irradiation can be received by the panel and utilized.

Solar panels according to embodiments of the disclosed subject matter can be used in both hot and cold climates for residential housing and commercial buildings. Any new high efficient solar modules can be integrated within this roofing panel structure. Because most solar roofing panels bond multiple layers together, due to environmental temperature and moisture change, de-lamination between layers severely reduces the life and efficiency of the panels. Panels according to the disclosed subject matter minimize the usage of glue thereby enhancing the interface integrity via a gradual transition of materials.

For a hybrid solar roofing system with a heat collector, a temperature difference between warm indoor air and cold roof material can induce the vapor condensation and degrade the indoor thermal comfort. However, by placing the heat sink, i.e., water tubes, onto a thick substrate as taught by the disclosed subject matter, the temperature difference is reduced thereby preventing vapor condensation.

From exposure to weather environments, solar roofing material properties and structural strength often decay over the service time. The life-cycle assessment and life-cycle cost analyses of a new solar panel cannot be directly conducted in a short test period. Because panels according to the disclosed subject matter include polymeric materials under the protection of a silicon photovoltaic layer from UV radiation, they are easier to maintain and recycle than existing panels.

Panels according to the disclosed subject matter are less costly to manufacture than known panels due to less usage of silicon in the thin film photovoltaic layer and integrated manufacturing. In addition, sustainability of manufacturing is improved by usage of recycled polymeric materials. The all-in-one piece structure provides simplified installation and maintenance of the integrated solar panels according to the disclosed subject matter.

In service, 85 to 95 percent solar irradiation can be absorbed by the photovoltaic module. Typically, only 7 to 25 percent of solar energy is utilized by a photovoltaic module and the majority is transferred into heat. However, the thermoelectric module typically has low thermal conductivity. Therefore, large temperature gradients will be produced within the thermoelectric layer and a higher electricity utilization efficiency will be obtained. Because the surface layer of the functionally graded material has a high thermal conductivity, the heat flux passed through the thermoelectric module layer is easily transferred to the water tubes and collected by water flow inside.

Because thermoelectric energy utilization efficiency depends on temperatures, which is different from systems utilizing only photovoltaic modules, the energy efficiency will be improved without reducing the energy efficiency existing photovoltaic modules. Also, due to the low thermal conductivity of the thermoelectric module, the amount of water consumed will be reduced. Finally, an additional layer, i.e., the thermoelectric module, will provide additional protection of the polymer materials below from UV radiation and thermal aging effects.

Although the disclosed subject matter has been described and illustrated with respect to embodiments thereof, it should be understood by those skilled in the art that features of the disclosed embodiments can be combined, rearranged, etc., to produce additional embodiments within the scope of the invention, and that various other changes, omissions, and additions may be made therein and thereto, without parting from the spirit and scope of the present invention.

What is claimed is:

1. A solar panel, comprising:
a top protective layer;
a thin-film photovoltaic layer adjacent said top layer;
a bottom polymeric substrate layer opposite said top layer; and
a functionally graded material interlayer positioned between said top and bottom layers, said interlayer including a first homogeneous polymeric composite layer below said thin film photovoltaic layer, a second homogeneous polymeric composite layer including water tubes below said first composite layer, and a substantially polymeric layer below said second composite layer and adjacent said bottom layer.

2. The panel according to claim 1, wherein said top protective layer is formed from a coating or glass-like material.

3. The panel according to claim 1, wherein said first homogeneous polymeric layer includes aluminum nitride and high density polyethylene.

4. The panel according to claim 1, wherein said second homogeneous polymeric layer includes aluminum and high density polyethylene.

5. The panel according to claim 1, wherein said substantially polymeric layer includes high density polyethylene.

6. The panel according to claim 1, wherein said thin-film photovoltaic layer includes at least one of silicon, other inorganic materials, organic dyes, and organic polymers.

7. The panel according to claim 1, wherein said overall thickness of said panel is about 20 mm to about 40 mm.

8. The panel according to claim 1, wherein said thickness of said bottom layer is about 10 mm to about 20 mm.

9. The panel according to claim 1, wherein said functionally graded material interlayer is positioned between said thin-film photovoltaic and bottom layers.

10. The panel according to claim 1, further comprising:
a thermoelectric module layer positioned between said thin-film photovoltaic layer and said functionally graded material interlayer.

11. A solar heating system, comprising:
a solar panel including:
a top protective layer;
a thin-film photovoltaic layer adjacent said top layer;
a bottom polymeric substrate layer opposite said top layer; and
a functionally graded material interlayer positioned between said top and bottom layers, said interlayer including a first homogeneous polymeric composite layer below said thin film photovoltaic layer, a second homogeneous polymeric composite layer including water tubes below said first composite layer, and a substantially polymeric layer below said second composite layer and adjacent said bottom layer;
a pump and a conduit for pumping a source of cold water into said water tubes at varying low rates;
a distribution sub-system for directing said source of cold water after it is heated within said water tubes elsewhere for consumption; and
a control system for controlling said pump and said distribution sub-system depending on temperatures within at least one of said solar panel, an interior of said water tubes, and an atmosphere outside said system.

12. The system according to claim 11, wherein said source of cold water is automatically introduced to said water tubes depending on temperatures within said solar panel.

13. The system according to claim 11, further comprising a source of warm water for introducing to said water tubes to melt ice and snow on said solar panel.

14. The system according to claim 11, wherein said top protective layer is formed from a coating or glass-like material.

15. The system according to claim 11, wherein said first homogeneous polymeric layer includes aluminum nitride and high density polyethylene.

16. The system according to claim 11, wherein said second homogeneous polymeric layer includes aluminum and high density polyethylene.

17. The system according to claim 11, wherein said substantially polymeric layer includes high density polyethylene.

18. The system according to claim 11, wherein said thin-film photovoltaic layer includes at least one of silicon, other inorganic materials, organic dyes, and organic polymers.

19. The system according to claim 11, wherein said functionally graded material interlayer is positioned between said thin-film photovoltaic and bottom layers.

20. The system according to claim 11, further comprising:
a thermoelectric module layer positioned between said thin-film photovoltaic layer and said functionally graded material interlayer.
